(19) United States
(12) Patent Application Publication
(10) Pub. No.: US 2026/0269469 A1
(43) Pub. Date: Sep. 10, 2026

(54) DUAL LNA/PA WITH CONFIGURABLE POLARISATION CONTROL

(71) Applicant: EnSilica plc, Wokingham (GB)

(72) Inventors: Alan Chi Wai WONG, ABINGDON (GB); Ian LANKSHEAR, ABINGDON (GB)

(21) Appl. No.: 19/544,926

(22) Filed: Feb. 19, 2026

(30) Foreign Application Priority Data
Feb. 19, 2025 (GB) 2502421.7

(51) Int. Cl. H01Q 3/36; H03H 11/16

(52) U.S. Cl. CPC H01Q 3/36; H03H 11/16

(57) ABSTRACT

An antenna circuit for processing a signal received by at least one antenna, the antenna circuit comprising a first input port and second input port, each configured to receive a feed from the at least one antenna, a 90 degree phase shifter arranged to shift a signal received at the first input port with respect to a signal received at the second input port by 90 degrees, at least one switchable phase shifter, connected to one of the first input port and the second input port, configured to impart a phase shift of 0 or 180 degrees on a received signal, a combiner, connected to the at least one switchable phase shifter, configured to output the sum of received signals; and a principal output port.

### CROSS REFERENCE TO RELATED APPLICATION

This application claims benefit of and priority to United Kingdom Patent Application No. 2502421.7, filed on Feb. 19, 2025, the content of which is hereby incorporated by reference in its entirety.

### FIELD OF THE INVENTION

The present disclosure relates to antennas, amplification circuits, and more particularly to the amplification of signals received from antennas or for transmitting electromagnetic waves.

### BACKGROUND

In electromagnetic wave propagation, linear polarisation corresponds to oscillation of the electric field in a single plane, whereby the oscillation is perpendicular to the propagation direction of the field. Circular or elliptical polarisation occurs when the horizontal and vertical components of the electric field oscillate out of phase to each other and combine to a rotating electric field vector. The circular polarisation vector can rotate in the right-hand direction or in the left-hand direction, depending on whether the horizontal component is 90° ahead or behind the vertical component.

Both linear and circular polarisation are used for wireless communication systems. Circular polarisation is used more commonly for satellite communication because it can maintain signal integrity in a variety of conditions. Signal integrity of circularly polarised light is maintained under reflections or misalignment. Circularly polarised electromagnetic radiation is also less sensitive to antenna orientation. The orientation of the transmitter preferably corresponds to the orientation of the receiver. For example, if the transmitter transmits right-handed circularly polarised electromagnetic waves, the receiver should also be configured to receive right-handed circularly polarised electromagnetic waves to maximise transmission.

Typically, an antenna for receiving circularly polarised waves has two outputs, denoted horizontal, H, and vertical, V. The signals in feeds H and V have a respective phase difference of 90°. An amplification device must account for this phase difference.

Typically, electronically steerable antenna arrays have multiple phase shifters or delay electronics at the different individual antennas for beam steering. The emission of the combined output can be directed by applying a phase difference between the individual antenna outputs A receiving array of antennas applies a corresponding reverse delay between individual received signals to process the signals. The adding of delays to individual outputs significantly reduces the power efficiency of the device. Other devices may reduce the number of beam steering electronics but may only support one circular polarisation direction. This can be mitigated by using multiple switches, but this comes at the cost of complexity and increased size.

Typically, antenna amplification devices also only support one type of antenna. For example, amplification devices may only support a dual feed antenna of fixed polarization orientation or only support two single feed antennas.

### SUMMARY

According to a first aspect of the invention, there is provided an antenna circuit for processing a signal received by at least one antenna, the antenna circuit comprising:
a first input port and second input port, each configured to receive a feed from the at least one antenna;
a 90 degree phase shifter arranged to shift a signal received at the first input port with respect to a signal received at the second input port by 90 degrees;
at least one switchable phase shifter, connected to one of the first input port and the second input port, configured to impart a phase shift of 0 or 180 degrees on a received signal;
a combiner, connected to the at least one switchable phase shifter, configured to output the sum of received signals; and a principal output port.

The antenna circuit may comprise two switchable phase shifters configured to impart a phase shift of 0 or 180 degrees on a received signal, one of the two switchable phase shifters connected to the first input port, and a second one of the two switchable phase shifters connected to the second input port. The combiner may be connected to the first phase shifter and the second phase shifter to combine output signals from the first phase shifter and the second phase shifter.

The antenna circuit may further comprise a first amplifier arranged after the first input port and a second amplifier arranged after the second input port.

The antenna circuit may further comprise: a first switch, connected to the first input port, configured to be switchable between: a first position in which the first input port is connected to the at least one switchable phase shifter; and a second position in which the first amplifier is connected to a second output port. The antenna circuit may comprise two switchable phase shifters, and a second switch, connected to the second input port, configured to switch between: a first position in which the second input port is connected to the second phase shifter; and a second position in which the second input port is connected to third output port. The first switch and second switch may be configured to switch to the first position when the first input port and second input port each receive an input from a dual feed antenna.

The first switch or the second switch may be configured to switch to the second position when the first input is connected to a single feed antenna or when the second input is connected to a second single feed antenna.

The combiner may be directly connected to the principal output port.

According to a second aspect of the invention, there is provided an antenna circuit for processing a signal before transmission of the signal by at least one antenna, the antenna circuit comprising: a principal input port; a power splitter, connected to the principal input port, configured to divide a signal received from the principal input port;
at least one switchable phase shifter, connected to an output of the power splitter, and configured to impart a phase shift of 0 or 180 degrees on a received signal;
two output ports, wherein at least one of the output ports is connected to the at least one switchable phase shifter; a 90 degree phase shifter arranged in one of the outputs of the power splitter.

The antenna circuit may comprise two switchable phase shifters, each switchable phase shifter configured to impart a phase shift of 0 or 180 degrees on a received signal, and each switchable phase shifter connected to an output of the power splitter.

The antenna circuit may further comprise a first amplifier arranged before the first one of said two output ports, and a second amplifier arranged before the second one of said two output ports.

The antenna circuit may further comprise a second input and a first switch, the first switch comprising an output connected to one of the two output ports, and the switch comprising an input arranged to switch between said second input port and a first output of said power splitter. The antenna circuit may further comprise a third input and a second switch, the second switch connected to the other one of the two output ports, and arranged to switch between said third input port and a second output of said power splitter.

The antenna circuit according to the first aspect of the second aspect may further comprise an antenna. The antenna may be one of: a square patch antenna, a round patch antenna, a patch antenna, a combination of two antennas, and a combination of two orthogonal dipole antennas.

According to the third aspect, there is provided an array of antennas and antenna circuits, wherein each of the antenna circuits in the array is an antenna circuit according to the first aspect, and wherein at least one of the antenna circuits in the array comprises a phase shifter arranged to impart a phase shift on the emitted or received signal in said at least one of the antenna circuits with respect to an emitted or received signal in another one of the antenna circuits.

According to the fourth aspect, there is provided a method of processing a signal received by at least one antenna, the method comprising: receiving two input signals from two output channels of the at least one antenna or from two antennas; imparting a 90 degree phase shift on one of the two input signals; imparting a switchable phase shift of 0 or 180 degrees on one of the two signals; combining the two signals after said steps of imparting a 90 degree phase shift and imparting a switchable 0 or 180 degree phase shift; output a combined signal.

The method may further comprise imparting a switchable phase shift of 0 or 180 degrees on the other one of the two signals. The method may further comprise amplifying the input signals before imparting a switchable phase shift on one or both of the signals.

The method may further comprise switching between feeding at least one of the input signals to the switchable phase shift, and feeding the at least one of the input signals to an output.

According to a fifth aspect, there is provided a method of processing a signal before transmission of the signal by at least one antenna, the method comprising: receiving a signal; splitting the signal into two signals; imparting a switchable phase shift of 0 or 180 degrees on one of the two signals; imparting a 90 degree phase shift on one of the two signals; transmitting the two signals to two input ports of an antenna, or to two antennas.

The method may further comprise imparting a switchable phase shift of 0 or 180 degrees on the other one of the two signals. The method may further comprise amplifying each of the two signals. The method may further comprise switching between transmitting one of the two signals generated by said splitting and a signal received at a second input.

### BRIEF DESCRIPTION OF THE DRAWINGS

FIG. 1 depicts an example of an amplification device supporting reversible circular polarisation connected to a dual feed antenna.

FIG. 2 depicts an example of an amplification device supporting one direction of circular polarisation connected to a dual feed antenna.

FIG. 3 depicts an example of an amplification device supporting reversible circular polarisation connected to a dual feed antenna.

FIG. 4 depicts an example of an amplification device connected to two single feed antennas.

FIG. 5 depicts an example of an amplification device designed to amplify inputs prior to transmission.

FIG. 6 is a flow diagram and

FIG. 7 is a flow diagram.

### DETAILED DESCRIPTION

Throughout the specification, the relative terms such as horizontal, vertical, top, and bottom are used to aid description of the device. The terms may be used in relation to the figures and do not imply a particular orientation of the device. Components such as phase shifter or secondary phase shifter may be equivalent to time delay electronics.

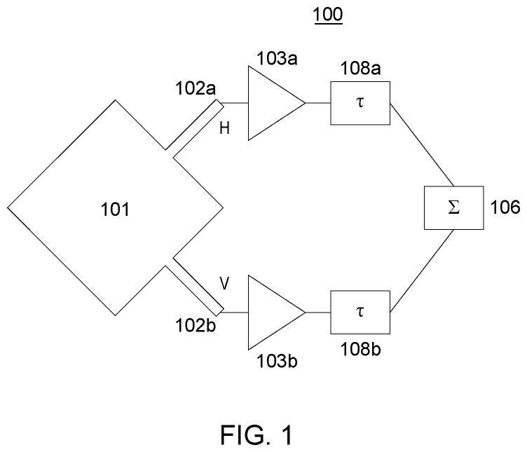

FIG. 1 presents a circuit diagram for an antenna amplification device 100 with configurable polarisation control connected to a dual output patch antenna, according to an embodiment. A circularly polarised beam will induce alternating electric currents in each of the outputs of the patch antenna. Components visible in FIG. 1 include: a dual output patch antenna 101, two output ports 102a and 102b, two amplifiers 103a and 103b electrically connected respectively to the two output ports, two phase shifters 108a and 108b electrically connected each of the amplifiers, respectively, and a combiner 106 which adds the outputs of the two phase shifters into a single output. In other embodiments, not all the components may be used. In other embodiments, additional components may be used.

The dual feed antenna 101 has two outputs denoted horizontal, H, and vertical, V. The dual feed antenna 101 is configured to receive polarised electromagnetic waves and output a signal based on the received waves.

The amplification device 100 can be conceptually divided into two branches. Components with a reference numeral suffix of “a” form part of the top branch. Components with a reference numeral suffix of “b” form part of the bottom branch.

The signal to the top branch 102a is input into amplifier 103a. The amplifiers 103a and 103b are configured to amplify the input signal from the dual feed antenna 101.

A circularly polarised beam will induce alternating electric currents in each of the outputs of the patch antenna, whereby a 90° phase difference between the horizontal and vertical components of the incoming beam is reflected in a 90° phase difference between the two electronic output signals from the antenna. The output of amplifier 103a is fed into a phase shifter 108a. The phase shifters 108a and 108b impart a phase shift on the input signal to account for the 90° phase difference between the two branches. The 90° phase shift can be applied in either branch which allows for receiving both left-handed and right-handed circularly polarised light. If the amplification device 100 is used as part of an array, the phase shifters also apply an additional phase shift for beam steering, whereby the additional phase shift is the same for both branches, but different to the phase shift in other antennas in the array.

The output of phase shifter 108a is fed into a combiner 106. Like the top branch, the bottom branch features the same components, and the components are arranged in the same way. The combiner 106 receives inputs from both the top and bottom branch outputs the sum of the inputs.

A disadvantage of the amplification device 100 is that the phase shifters impart both a 90° phase shift in one of the arms, and also a phase shift for beam steering. Further, there is a phase shifter in each branch. This makes the device less efficient because of the additional electronics and additional spatial requirements for the electronics architecture.

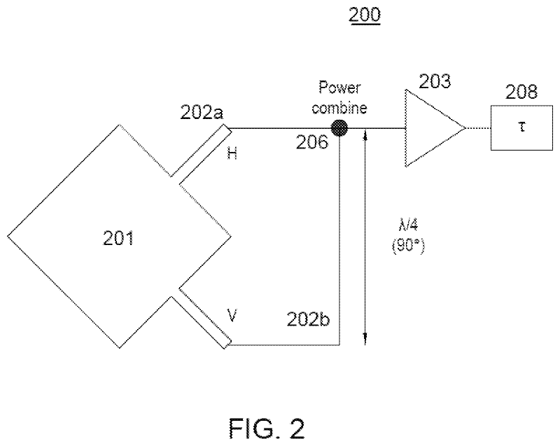

FIG. 2 presents an amplification device 200 which has half the beam steering hardware, according to an embodiment. Components visible in FIG. 2 include: a dual feed antenna 201, two input ports 202a and 202b, a combiner 206, an amplifier 203, and a phase shifter 208.

Unlike the FIG. 1 embodiment, a fixed 90° phase shift is applied to only one of the branches. The combiner 206 sums the two inputs 202a and 202b before amplification. The output of the combiner is directed into the amplifier 203. The amplified signal from the amplifier is then input into a phase shifter 208. The phase shifter 208 imparts a phase shift to account for beam steering.

In this way, there is only one phase shifter for beam steering. Further, the number of amplifiers has been halved. Thus, the device is more efficient. However, because a fixed 90° phase shift is imparted in one of the branches, the device is only capable of receiving circularly polarised light with one handedness and it would not be able to process a signal from the other handedness.

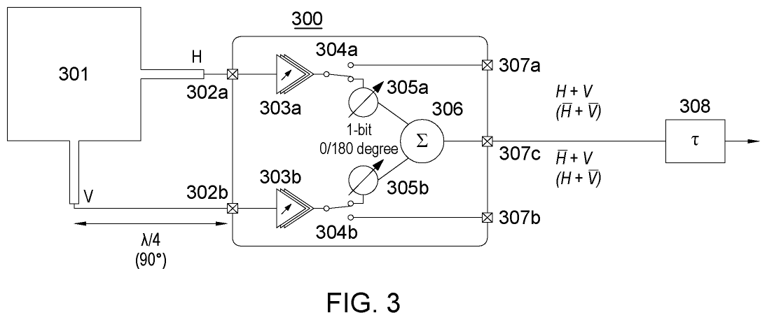

FIG. 3 presents a circuit diagram for an antenna device 300 with configurable polarisation control connected to a dual output antenna, according to an embodiment. Components visible in FIG. 3 include: a dual output antenna 301, a fixed delay line of 90° in one of the output lines with respect to the other output line, two input ports 302a 302b, two low noise amplifiers 303a and 303b, two switches 304a and 304b, two 1-bit 0/180° phase shifters 305a and 305b, a combiner 306, three output ports 307a, 307b, and 307c, and a secondary phase shifter 308. In other embodiments, not all the components may be used. In other embodiments, additional components may be used. The expression ‘1-bit’ phase shifter is used to indicate that the phase shifter is switchable between two discrete values of 0° and 180°. We also describe this as imparting a switchable phase shift of 0° or 180° onto a signal.

The dual feed patch antenna 301 has two outputs denoted horizontal, H, and vertical, V. The dual feed antenna 301 is configurable to receive electromagnetic signals with different polarisations and output a signal based on the received signals.

Like FIG. 1, the amplification device 300 can be conceptually divided into two branches. Components with a reference numeral suffix of “a” form part of the top branch. Components with a reference numeral suffix of “b” form part of the bottom branch.

The horizontal feed H is connected to the top branch input 302a. The input 302a is connected to low noise amplifier 303a. The low noise amplifiers 303a and 303b are configured to amplify the input signal from the dual feed antenna 301. The low noise amplifiers 303a and 303b may be differential amplifiers to reduce common noise effects.

The switch 304a is located at the output of the low noise amplifier 303a. The switches 304a and 304b are configured to switch between two positions. A first position connects the low noise amplifier 303a to the 1-bit 0/180° phase shifter 305a. A second position connects the low noise amplifier 303a to the output 307a. In some embodiments, the switches may not be present. Instead, in some embodiments the low noise amplifiers 303a and 303b may be directly connected to the 1-bit 0/180° phase shifter 305a and 305b. In other embodiments, the low noise amplifiers 303a and 303b may be directly connected to output ports 307a and 307b, respectively.

The 1-bit 0/180° phase shifters 305a and 305b are configured to impart either a 0° or 180° phase shift on the input signal. The phase shift imparted may be dependent on the polarisation of the received electromagnetic waves. In some embodiments, only one of the 1-bit 0/180° phase shifters may be present. Using two 1-bit 0/180° phase shifters gives greater flexibility. In some instances, use of one of the 1-bit 0/180° phase shifters may produce a better output signal than use of the other, depending on the position of the antenna and second order effects. The ability to select one or the other phase shifter therefore provides an advantage. Additionally, using two 1-bit 0/180° phase shifters gives better matching for signal paths. This is important from a timing or phase viewpoint.

Like the top branch, there is a bottom branch with the same components and connected in a corresponding way. However, a 90° phase shift is applied to the vertical feed V of the dual feed antenna 301 before the input 302b. In other embodiments, the 90° phase shift may be applied to the horizontal feed H. In other embodiments, the 90° phase shift may be applied after input 302a or 302b. In other embodiments, the 90° phase shift may be applied directly after amplification. In other embodiments the 90° phase shift may be applied after the 1-bit 0/180° phase shifters 305a and 305b. The advantage of applying the 90° phase shift in the antenna feed increases the simplicity of the design and increases the efficiency of the device. The 90° phase shift can be implemented by way of a delay line in the respective channel, or in other ways known to the skilled person.

The horizontal and vertical components of a circularly polarised signal have a 90° phase difference, and after receipt by the two orthogonal channels of the antenna the same phase difference will be present between the two electrical signals. After applying the 90° phase shift, the 90° phase difference has been compensated for. However, the inventors have realised that a circuit can be provided which can process both left- and right-handed polarisation. After compensating for the 90° phase difference, the two electrical signals are in phase for one of the two types of circular polarisation, in which case no further phase shift needs to be applied. For the other of the two types of circular polarisation, the two electrical signals are 180° out of phase with respect to each other. A further 180° phase shift, which amounts to an inversion, is applied to either one of the two signals using one of the two 1-bit 0/180° phase shifters.

The output of both 1-bit 0/180° phase shifters 305a and 305b is inputted into the combiner 306. The combiner 306 sums the two inputs and has a single output 307c. The output 307c is directed into the secondary phase shifter 308. The secondary phase shifter 308 imparts a phase shift on the inputted signal and outputs a phase shifted signal. In some embodiments the secondary phase shifter 308 may not be present. The secondary phase shifter may be used for beam steering, because a different phase shift is applied to different antenna circuits in the array. The collective output signal of an array of transmitters can be shaped into a beam by constructively and destructively interfering the individual outputs of the antennas in the array by applying different phase shifts. The reverse process can be applied when receiving a shaped beam, by applying a reverse phase shift to individual circuits in the array.

When the dual feed antenna 301 receives circularly polarised electromagnetic waves, the signals in the two feeds, H and V, have a respective phase difference of 90°. The 90° phase shifter accounts for this difference, and the switches 304a and 304b are set to be in the first position. Therefore, the low noise amplifiers 303a and 303b are both connected to the 1-bit 0/180° phase shifters 305a and 305b.

Consider the example if the signal from V is 90° ahead of the signal from H:

$$H = sin ( x ) , \\ {V}_{1} = sin ( x + \frac{π}{2} ) .$$

At the input 302b, after applying the 90° phase shift, the input is:

$${V}_{1}^{′} = sin ( x + \frac{π}{2} - \frac{π}{2} ) = sin ( x ) .$$

Thus, H and V′₁ are in phase and can be summed at the combiner 306. Both 1-bit 0/180° phase shifters are set to 0, or both are set to 180°. These two options are indicated as H+V and H̅+V̅.

If the signal from V is 90° behind the signal from H (the handedness of the circularly polarised waves has been reversed):

$$H = sin ( x ) , {V}_{2} = sin ( x - \frac{π}{2} ) .$$

At the input 302b, after applying the same 90° phase shift, the input is:

$${V}_{2}^{′} = sin ( x - \frac{π}{2} - \frac{π}{2} ) = sin ( x - π ) .$$

Thus, H and

$${V}_{2}^{′}$$

are out or phase and cannot be summed at the combiner 306.

If a 180-degree phase shift is applied to signal V′₂ using the 1-bit 0/180° phase shifter 305b:

$$\overline{{V}_{2}^{′}} = - {V}_{2}^{′} = - sin ( x - π ) = sin ( x ) .$$

Therefore, H and

$$\overline{{V}_{2}^{′}}$$

are in phase and can be summed at the combiner 306. The 1-bit 0/180° phase shifter 305a is set to 0. Alternatively, phase shifter 305b is set to 0 and phase shifter 305a is set to 180°. These two options can be indicated as: H+V̅, H̅+V. Given that either phase shifter can be used, a circuit in which one of the 1-bit 0/180° phase shifters is omitted can achieve the same overall effect, but, as mentioned previously, the inventors have realised that using one of the phase shifters sometimes gives a slightly better result than the other in practice, so having the option to try both options and select the best option for optimising the signal is preferable. Additionally, as mentioned above, using two 1-bit 0/180° phase shifters gives better matching for signal paths. This is important from a timing or phase viewpoint.

Depending on which or both of the 1-bit 0/180° phase shifters 305 are used, there are four possible outputs from the combiner: H+V, H+V̅, H̅+V, and H̅+V̅.

In this way, the amplification device 300 shown in FIG. 3 can amplify the signals from both right-handed and left-handed circularly polarised waves. The design is easily realised in integrated circuits.

The antenna illustrated in FIG. 3 is a square patch antenna, arranged to receive the orthogonal modes of an electromagnetic signal. The skilled person will appreciate that other antennas known in the art can be used, such as a round patch antenna, or a patch antenna with a different shape. A combination of two antennas can also be used, and each of the inputs is then connected to a different antenna, whereby each of the two antennas received a different component of the field. For example, a combination of two orthogonal dipole antennas can be used. Otherwise, the circuit design will be the same when different antennas are selected.

In comparative examples, other amplification devices may require double the beamforming electronics for electronically steerable phase arrays and may not be able to amplify the signals of circularly polarised waves with different handedness. The advantage of the present invention is that only one secondary phase shifter 308 is required. This increases the efficiency of the device when compared to comparative examples. Implementing a 180° phase shift in the device is much simpler than implementing a 90° phase shift, or any other phase shift for beam steering. This is because the device makes use of a differential integrated circuit implementation. This reduces common-mode noise and interference. Inversion of differential signals gives a 180° phase shift and is easily implemented by “swapping” the outputs. Another advantage of the present invention is the low number of switches required. The switches 304 are only used for changing between antenna types. In comparative examples, multiple switches are used to allow for receiving different polarisation directions. This adds complexity and may decrease the speed at which different polarisation directions can be received.

The amplification device described above has a simple antenna feed structure allowing for low loss and easy connection. The electronics to allow for different handedness of circular polarisation is implemented after the low noise amplifiers which maximises the signal to noise ratio. In comparative examples, other direct antenna feed implementations to allow for different handedness of circular polarisation are more lossy and are difficult to implement on a phased array panel.

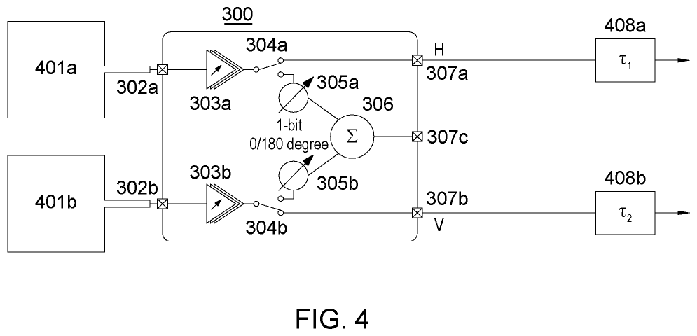

FIG. 4 presents a circuit diagram of amplification device 300 connected to two single feed antennas 401a and 401b, and two secondary phase shifters 408a and 408b, according to an example.

The two single feed antennas 401a and 401b are each configured to receive linear or a single component of polarised electromagnetic waves and output an electrical signal based on the received waves.

The two single feed antennas attached to the amplification device 300 are in different physical locations. This is unlike a dual feed antenna which has one location and two feeds. Different phase shifts will need to be applied to the signal from each antenna due to the different physical locations of the antennas. Therefore, unlike the embodiment shown in FIG. 3, the switches 304a and 304b are set to the second position. The phase shift imparted by each secondary phase shifter 408a and 408b is dependent on the physical location of each antenna. The phase shifted imparted is also dependent on the beam steering required.

The amplification device 300 shown in FIGS. 3 and 4 can support a dual feed antenna or two single feed antennas. In comparative examples, the beamforming electronics are configured for a single type of antenna only.

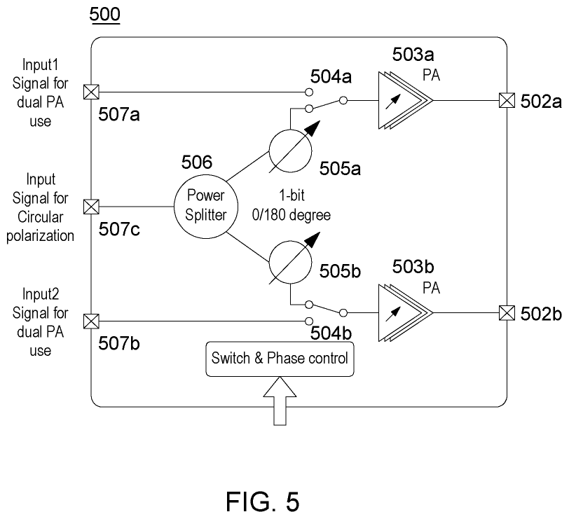

FIG. 5 presents a circuit diagram for an amplification device with configurable polarisation control, according to an example. This circuit diagram can be used for generating a signal to send to an antenna, instead of receiving a signal. However, the same inventive concept is shared with the example described above. Components visible in FIG. 5 include: two power amplifiers 503a and 503b, two switches 504a and 504b, two 1-bit 0/180° phase shifters 505a and 505b, a power splitter 506, and three inputs 507a, 507b, and 507c.

Like FIG. 1, components with a reference numeral suffix of “a” form part of the top branch. Components with a reference numeral suffix of “b” form part of the bottom branch.

The centre input 507c, is configured to receive a signal for generating and transmitting circularly polarised waves.

The outer inputs 507a and 507b are configured to receive signals for transmitting linearly polarised waves, or circularly polarised waves.

The centre input 507c is connected to the power splitter 506. The power splitter 506 is like the combiner 506 of FIGS. 3 and 4 but operated in reverse. It has 1 input and 2 outputs, rather than 2 inputs and 1 output.

The outputs of the power splitter 506 are connected to the 1-bit 0/180° phase shifters 505a and 505b. The switches 504a and 504b are configured similarly to in FIGS. 3 and 4. In FIG. 5, the switches are in the first position. The switches connect the output of the 1-bit 0/180° phase shifters 505a and 505b to the power amplifiers 503a and 503b. In a second position, the switches 504a and 504b connect inputs 507a, 507b to power amplifiers 503a and 503b, respectively, while the outputs of the phase shifters are not connected to an output.

The power amplifiers 503a and 503b are configured to amplify an inputted signal, whether from the phase shifters or the outer inputs 507.

If a circularly polarised wave is to be transmitted, the signal is inputted at input 507c. It is also possible to use outer inputs 507 to generate circular polarisation, if the inputs are initially in phase and a 90° phase difference is applied to the inputs, or if a 90° phase difference already exists between the two inputs no further phase difference needs to be applied. The power splitter 506 splits the signal input into two branches.

One output of the power splitter is directed into the top branch. The output of the power splitter is inputted into 1-bit 0/180° phase shifter 505a. The 1-bit 0/180° phase shifter 505a imparts either a 0° or 180° phase shift on the inputted signal depending on the desired handedness of the wave to be transmitted. Switch 504a is connected to the output of 1-bit 0/180° phase shifter 505a. For transmitting circularly polarised waves, the switch 504a is set to the first position and connects the 1-bit 0/180° phase shifter to the power amplifier 503a. The power amplifier 503a amplifies the inputted signal. The output of the power amplifier 503a is directed to output 502a.

The other output of the power splitter is directed into the bottom branch. The bottom branch features the same components as the top branch and is arranged the same way.

For transmitting circularly polarised waves, the outputs 502a and 502b are connected to a dual feed antenna and a 90° phase shift is applied to one of the outputs. The 90° phase difference can be applied by adding a delay line, for example.

If a linearly polarised wave is to be transmitted, the signal is inputted in inputs 507a and 507b. The switches 504a and 504b are set to the second position to connect inputs 507a and 507b to power amplifiers 503a and 503b, respectively.

For transmitting linearly polarised waves, each of outputs 502a and 502b are connected to a different single feed antenna. Further, inputs 507a and 507b will each require a phase shifter for beam steering and accounting for the different physical locations of the antennas. It is also possible to take the outputs of the 1-bit phase shifters and send each to an individual antenna in order to emit linearly polarised signals.

The advantage of the present amplification device is that by substituting the low noise amplifiers of the FIGS. 3 and 4 embodiments for power amplifiers, the device can be operated in reverse as a transmitter rather than a receiver. Thus, the simple broad structure of the device remains the same whether acting as a receiver or transmitter. This eases manufacture of the device and reduces cost.

The amplification device described in FIGS. 3-5 can be implemented in a small chip size. Thus, there are lower insertion losses at higher (mmWave) frequencies as antenna feeds can be short. The low chip size also means that the device can be integrated into mmWave phase array antenna systems. In comparative examples, beam forming chips, with low noise amplifiers and fine delay elements/phase shifting steering electronics integrated, are larger and more difficult to implement in a high frequency phased array patch antenna where the antenna spacing is typically 2/2. A 2.4 GHz carrier frequency may be used, as is typical for WiFi and other standards, but the invention is not limited to this example. Further, the implementation is simple and efficient in an integrated circuit design. The electromagnetic field will further carry information encoded into the carrier frequency, for example by frequency modulation or amplitude modulation, but that is standard knowledge of the skilled person and will therefore not be described here in detail. The decoding of the message will take place at additional electronics to which the output signal is sent, which again will not be described because the concepts described herein relate to the antenna circuit, and not subsequent electronics.

The device could be implemented on a chip using integrated circuits. The integrated circuits may be CMOS, CMOS-SOI or BiCMOS using silicon or SiGe technologies, or pHEMT using GaAs or GaN technologies. The skilled person will appreciate that there are many methods to implement delays in integrated circuits. The 180° shifts can be formed by a straightforward signal inversion which can easily be implemented in differential circuits, while the 90° and other phase shifts need more active or passive elements in the signal path to implement.

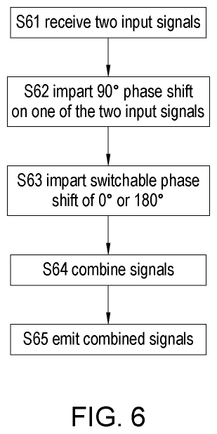

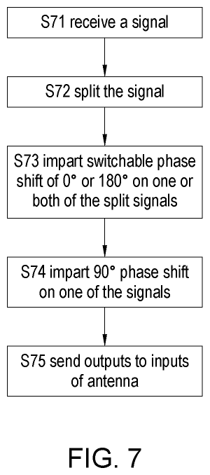

The key steps of the methods described herein are illustrated in FIGS. 6 and 7.

FIG. 6 shows the steps of receiving two input signals (S61), imparting a 90° phase shift on one of the two input signals (S62), impart a switchable phase shift of 0° or 180° onto one or both of the two signals (S63) before combining the signals (S64) and outputting the combined signals (S65).

FIG. 7 illustrates the reverse process when sending a message. A signal is received (S71) from upstream electronics. The received signal is split (S72) and a switchable phase shift of 0° or 180° is imparted onto one or both of the split signals (S73). A 90° phase shift is imparted on one of the two split signals (S74), and each of the signals is sent to inputs of an antenna (S75)

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. An antenna circuit for processing a signal received by at least one antenna, the antenna circuit comprising:
a first input port and second input port, each configured to receive a feed from the at least one antenna;
a 90 degree phase shifter arranged to shift a signal received at the first input port with respect to a signal received at the second input port by 90 degrees;
at least one switchable phase shifter, connected to one of the first input port and the second input port, configured to impart a phase shift of 0 or 180 degrees on a received signal;
a combiner, connected to the at least one switchable phase shifter, configured to output the sum of received signals; and
a principal output port.

2. The antenna circuit according to claim 1, comprising two switchable phase shifters configured to impart a phase shift of 0 or 180 degrees on a received signal, one of the two switchable phase shifters connected to the first input port, and a second one of the two switchable phase shifters connected to the second input port.

3. The antenna circuit according to claim 2, wherein the combiner is connected to the first phase shifter and the second phase shifter to combine output signals from the first phase shifter and the second phase shifter.

4. The antenna circuit according to claim 1, further comprising a first amplifier arranged after the first input port and a second amplifier arranged after the second input port.

5. The antenna circuit of claim 1, wherein the antenna circuit further comprises:
a first switch, connected to the first input port, configured to be switchable between:
a first position in which the first input port is connected to the at least one switchable phase shifter; and
a second position in which the first amplifier is connected to a second output port.

6. The antenna circuit of claim 5 wherein the antenna circuit comprises two switchable phase shifters, and
a second switch, connected to the second input port, configured to switch between:
a first position in which the second input port is connected to the second phase shifter; and
a second position in which the second input port is connected to third output port.

7. The antenna circuit of claim 6, wherein the first switch and second switch are configured to switch to the first position when the first input port and second input port each receive an input from a dual feed antenna.

8. The antenna circuit of claim 6, wherein the first switch or the second switch are configured to switch to the second position when the first input is connected to a single feed antenna or when the second input is connected to a second single feed antenna.

9. The antenna circuit of claim 1, wherein the combiner is directly connected to the principal output port.

10. An antenna circuit for processing a signal before transmission of the signal by at least one antenna, the antenna circuit comprising:
a principal input port;
a power splitter, connected to the principal input port, configured to divide a signal received from the principal input port;
at least one switchable phase shifter, connected to an output of the power splitter, and configured to impart a phase shift of 0 or 180 degrees on a received signal;
two output ports, wherein at least one of the output ports is connected to the at least one switchable phase shifter;
a 90 degree phase shifter arranged in one of the outputs of the power splitter.

11. The antenna circuit of claim 10, comprising two switchable phase shifters, each switchable phase shifter configured to impart a phase shift of 0 or 180 degrees on a received signal, and each switchable phase shifter connected to an output of the power splitter.

12. The antenna circuit of claim 10, further comprising a first amplifier arranged before the first one of said two output ports, and a second amplifier arranged before the second one of said two output ports.

13. The antenna circuit of claim 10, further comprising a second input and a first switch, the first switch comprising an output connected to one of the two output ports, and the switch comprising an input arranged to switch between said second input port and a first output of said power splitter.

14. The antenna circuit of claim 13, further comprising a third input and a second switch, the second switch connected to the other one of the two output ports, and arranged to switch between said third input port and a second output of said power splitter.

15. The antenna circuit of claim 1, further comprising an antenna.

16. The antenna circuit of claim 15, wherein the antenna is one of: a square patch antenna, a round patch antenna, a patch antenna, a combination of two antennas, and a combination of two orthogonal dipole antennas.

17. An array of antennas and antenna circuits, wherein each antenna in the array is an antenna according to claim 15, wherein each of the antenna circuits in the array is an antenna circuit comprising: a first input port and second input port, each configured to receive a feed from the at least one antenna; a 90 degree phase shifter arranged to shift a signal received at the first input port with respect to a signal received at the second input port by 90 degrees; at least one switchable phase shifter, connected to one of the first input port and the second input port, configured to impart a phase shift of 0 or 180 degrees on a received signal; a combiner, connected to the at least one switchable phase shifter, configured to output the sum of received signals; and a principal output port, and
wherein at least one of the antenna circuits in the array comprises a phase shifter arranged to impart a phase shift on the emitted or received signal in said at least one of the antenna circuits with respect to an emitted or received signal in another one of the antenna circuits.

18. A method of processing a signal received by at least one antenna, the method comprising:
receiving two input signals from two output channels of the at least one antenna or from two antennas;
imparting a 90 degree phase shift on one of the two input signals;
imparting a switchable phase shift of 0 or 180 degrees on one of the two signals;
combining the two signals after said steps of imparting a 90 degree phase shift and imparting a switchable 0 or 180 degree phase shift;
output a combined signal.

19. The method of claim 18, further comprising imparting a switchable phase shift of 0 or 180 degrees on the other one of the two signals.

20. The method of claim 18, further comprising amplifying the input signals before imparting a switchable phase shift on one or both of the signals.

21. The method of claim 19, further comprising switching between feeding at least one of the input signals to the switchable phase shift, and feeding the at least one of the input signals to an output.

22. A method of processing a signal before transmission of the signal by at least one antenna, the method comprising:
receiving a signal;
splitting the signal into two signals;
imparting a switchable phase shift of 0 or 180 degrees on one of the two signals;
imparting a 90 degree phase shift on one of the two signals;
transmitting the two signals to two input ports of an antenna, or to two antennas.

23. The method of claim 22, further comprising imparting a switchable phase shift of 0 or 180 degrees on the other one of the two signals.

24. The method of claim 22, further comprising amplifying each of the two signals.

25. The method of claim 22, further comprising switching between transmitting one of the two signals generated by said splitting and a signal received at a second input.
